(19) United States
(12) Patent Application Publication
(10) Pub. No.: US 2026/0033361 A1
(43) Pub. Date: Jan. 29, 2026

(54) SEMICONDUCTOR ARRANGEMENT COMPRISING A SEMICONDUCTOR ELEMENT, A SUBSTRATE AND AT LEAST ONE WIRING ELEMENT

(71) Applicant: Siemens Aktiengesellschaft, 80333 München (DE)

(72) Inventors: MICHAEL KÄSBAUER, Nürnberg (DE); LUKAS MAIER, Neunkirchen am Brand (DE); BERND ROPPELT, Unterhaid (DE); JENS SCHMENGER, Forchheim (DE)

(73) Assignee: Siemens Aktiengesellschaft, 80333 München (DE)

(21) Appl. No.: 18/996,200

(22) PCT Filed: May 31, 2023
(86) PCT No.: PCT/EP2023/064508

§ 371 Date: Jan. 17, 2025

(30) Foreign Application Priority Data
Jul. 29, 2022 (EP) 22187838.2

(51) Int. Cl. H01L 23/00; H01L 23/498; H02M 3/00; H02M 7/00

(52) U.S. Cl. CPC H01L 24/48; H01L 23/49838; H01L 24/32; H01L 24/73; H01L 24/85; H01L 2224/32227; H01L 2224/48091; H01L 2224/48105; H01L 2224/48227; H01L 2224/4846; H01L 2224/73265; H01L 2224/85205; H01L 2924/13055; H02M 3/003; H02M 7/003

(57) ABSTRACT

A semiconductor arrangement includes a substrate including a substrate metallization having line sections which are arranged so as to be electrically insulated from one another. A semiconductor element is connected to a first line section of the substrate metallization and has a contact surface on a side facing away from the substrate. A wiring element connects the contact surface of the semiconductor element to the substrate. The wiring element includes a first connecting section connecting the contact surface to a second line section of the substrate metallization, and a second connecting section connects the contact surface to a third line section of the substrate metallization, with the second line section and the third line section of the substrate metallization being designed such that the first connecting section and the second connecting section have an asymmetrical current flow during operation of the semiconductor arrangement.

The invention relates to a semiconductor arrangement with a semiconductor element, a substrate and at least one wiring element.

Further, the invention relates to a power converter with at least one semiconductor arrangement of this kind.

Moreover, the invention relates to a method for producing a semiconductor arrangement of this type, wherein the semiconductor element is connected, in particular adhesively bonded, to the substrate, wherein, in a further step, the contact surface of the semiconductor element is connected to the substrate via the at least one wiring element.

Furthermore, the invention relates to a computer program product comprising commands which, when the program is executed by a computer, cause the computer to simulate a behavior of a semiconductor arrangement of this kind.

A semiconductor module of this kind is generally used in a power converter. A power converter should be taken to mean, for example, a rectifier, an inverter, a converter or a DC-DC converter. The semiconductor elements used in the semiconductor module are, inter alia, transistors, Triacs, thyristors or diodes. Transistors are designed, for example, as insulated gate bipolar transistors (IGBTs), field effect transistors or bipolar transistors. The semiconductor elements of a semiconductor arrangement are customarily contacted via wiring elements on a substrate. Wiring elements of this kind can comprise, inter alia, bonding wires and/or bonding tapes. In particular, load contacts of a semiconductor element, inter alia an emitter contact of an IGBT, are customarily contacted with a plurality of wiring elements on the substrate.

Patent application DE 11 201 9 000 660 T5 describes a semiconductor apparatus comprising: a substrate having a main surface; a plurality of conductor patterns provided on the main surface; a plurality of switching elements arranged on the plurality of conductor patterns in order to connect collector electrodes; and one or more wiring element(s) which directly connect emitter electrodes of the switching elements which are arranged on different conductor patterns and are connected in parallel between the plurality of switching elements.

During operation of the semiconductor elements, wiring elements can detach from the load contact, and this results in a failure of the semiconductor arrangement. More robust wiring results in improved reliability of the semiconductor arrangement.

Against this background, the object of the present invention is to disclose a semiconductor arrangement which has improved reliability.

The object is inventively achieved by a semiconductor arrangement having a semiconductor element, a substrate and at least one wiring element, wherein the substrate has a substrate metallization with line sections arranged so as to be electrically insulated from one another, wherein the semiconductor element is connected, in particular adhesively bonded, to a first line section of the substrate metallization, wherein the semiconductor element has a contact surface on a side facing away from the substrate, wherein the contact surface of the semiconductor element is connected to the substrate via at least one wiring element, wherein the at least one wiring element has a first connecting section, which connects the contact surface to a second line section of the substrate metallization, and a second connecting section which connects the contact surface to a third line section of the substrate metallization, wherein the second and third line sections of the substrate metallization are configured such that the first connecting section and the second connecting section have an asymmetrical current flow during operation of the semiconductor arrangement.

Further, the object is inventively achieved by a power converter with at least one semiconductor arrangement of this kind.

Moreover, the object is inventively achieved by a method for producing a semiconductor arrangement of this kind, wherein the semiconductor element is connected, in particular adhesively bonded, to the substrate, wherein, in a further step, the contact surface of the semiconductor element is connected to the substrate via the at least one wiring element.

Furthermore, the object is inventively achieved by a computer program product comprising commands which, when the program is executed by a computer, cause the computer to simulate, in particular thermal, mechanical and/or electrical, behavior of a semiconductor arrangement of this kind.

The advantages and preferred embodiments cited below with respect to the semiconductor arrangement may be transferred analogously to the power converter, the method and the computer program product.

The invention is based on the idea of improving the reliability of a semiconductor arrangement in that the probability of failure during operation of the semiconductor arrangement is significantly reduced by wiring elements detached from a semiconductor element. A semiconductor arrangement of this kind has a substrate with a substrate metallization. The substrate metallization is designed in a structured manner, that is to say it has line sections arranged so as to be electrically insulated from one another. The semiconductor element is connected, in particular adhesively bonded, to a first line section of the substrate metallization. The adhesively-bonded connection is produced, for example, by soldering, sintering or adhesion. Furthermore, the semiconductor element has a contact surface on a side facing away from the substrate, which contact surface is connected to the substrate via at least one wiring element. For example, the semiconductor element is designed as an IGBT, which is soldered or sintered on the collector side to the first line section of the substrate metallization, while it is connected to the substrate via the at least one wiring element on the emitter side. The at least one wiring element is designed, for example, as a bonding wire or bonding tape, it being possible to produce the connection between the substrate and the contact surface of the semiconductor element by means of ultrasonic bonding connections. The at least one wiring element comprises a first connecting section which establishes a connection of the contact surface to a second line section of the substrate metallization. If current, in particular load current, flows through the at least one wiring element, a shear force acts on connections, in particular ultrasonic bonding connections, between the contact surface of the semiconductor element and the wiring element.

In order to counteract a shear force of this kind, the at least one wiring element comprises a second connecting section, which connects the contact surface to a third line section of the substrate metallization, wherein the first line section, the second line section and the third line section are arranged so as to be electrically insulated from one another on the substrate. The second and third line sections of the substrate metallization are configured such that the first connecting section and the second connecting section of the at least one wiring element have an asymmetrical current flow during operation of the semiconductor device. This is the case, inter alia, if the second or the third line section, apart from the connection to the at least one wiring element, are arranged in a floating manner, so a current flows from the semiconductor arrangement at least predominantly, in particular substantially exclusively, via the first or second connecting section of the at least one wiring element. As a result of the additional connection of the at least one wiring element via the second connecting section to the third line section, which is also referred to as “overbonding” a counterforce of the shear force counteracts, so the connections of the at least one wiring element to the contact surface, in particular under load, are more robust, and this has a positive effect on the reliability of the semiconductor arrangement and prolongs its service life.

A computer program product which comprises commands which, when the program is executed by a computer, cause the computer to simulate, in particular thermal, mechanical and/or electrical, behavior of the described semiconductor arrangement can comprise or be embodied as a “digital twin”, also referred to as “digital twin”. A digital twin of this kind is represented, for example, in the patent application US 2017/0286572 A1. The disclosure of US 2017/0286572 A1 is incorporated by reference in the present application. The “digital twin” is, for example, a digital representation of the components relevant to the operation of the semiconductor arrangement.

A further embodiment provides that the second and the third line section of the substrate metallization are arranged on opposite sides of the semiconductor element. The opposite arrangement can counteract the counterforce of the shear force running parallel, so optimum robustness can be achieved.

A further embodiment provides that a first current, in particular load current, flowing through the first connecting section of the at least one wiring element is greater by one hundred times, in particular by one thousand times, than a second current flowing through the second connecting section of the at least one wiring element. This is the case, inter alia, if the third line section, apart from the connection to the at least one wiring element, is arranged in a floating manner, while the second line section is connected, for example, to an AC or DC terminal. In this way, in particular under load, an optimal robustness of the connections of the at least one wiring element to the contact surface is achieved.

A further embodiment provides that the third line section connected to the second connecting section of the at least one wiring element is arranged in a no-load manner on the substrate. A no-load arrangement of the third line section means that, apart from the at least one wiring element, it is not connected to any further components in an electrically conductive manner. In this way, an optimum robustness of the connections of the at least one wiring element to the contact surface is achieved, in particular under load.

A further embodiment provides that the first connecting section and the second connecting section of the at least one wiring element are designed to be substantially axially symmetrical in respect of an axis of symmetry. By means of a substantially axisymmetric arrangement, shear forces that occur are optimally compensated by counterforces that counteract the shear forces.

A further embodiment provides that the at least one wiring element has a third connecting section which connects the third line section of the substrate metallization to a contact surface of a further semi-conductor element. For example, the semiconductor element is designed as an IGBT, while the further semiconductor element is designed as a diode connected antiparallel to the semiconductor element. Alternatively, the further semiconductor element can be designed, inter alia, as a further IGBT connected in parallel with the semiconductor element designed as an IGBT. An arrangement of this kind achieves an improved robustness of the connections of the at least one wiring element to the contact surfaces of the semiconductor elements, and this has a positive effect on the reliability of the semiconductor arrangement and prolongs its service life.

A further embodiment provides that the semiconductor arrangement comprises a plurality of wiring elements for connecting the contact surface to the second and the third line sections. An embodiment of this kind is advantageous, in particular, for higher load currents. Furthermore, parasitic inductances are reduced by a parallel connection of wiring elements, and this results in lower switching losses.

A further embodiment provides that the semiconductor element is wider on a side facing the third line section than the third line section, wherein a main current path of the first line section is embodied to extend past the third line section on both sides. For example, a load current flows to the semiconductor element via the first line section. In this case, a main current path of the load current past the third line section on both sides. Improved current conduction is achieved by a narrower embodiment of the third line section, and this results, for example, in lower losses.

A further embodiment provides that the main current path of the first line section is embodied so as to extend substantially symmetrically past the third line section. An optimized current conduction is achieved by an embodiment of this kind of the arrangement.

A further embodiment provides that more wiring elements are connected to the second line section than to the third line section. For example, at least one wiring element, in particular at least one outer wiring element, has no second connecting section for connection to the third line section, as a result of which a narrower embodiment of the third line section is made possible, and this results in improved current conduction.

A further embodiment provides that the third line section of the substrate metallization comprises at least two wiring islands which are arranged so as to be electrically insulated from one another and which are arranged in a no-load manner on the substrate, wherein at least one wiring element respectively is connected to one of the wiring islands of the third line section via the respective second connecting section. A divided arrangement of this kind enables improved current conduction, and this results, for example, in lower losses.

A further embodiment provides that two wiring islands are arranged on the substrate in such a way that a main current path is embodied between the wiring islands. For example, a load current flows between the wiring islands to the semiconductor element. Losses are reduced by a direct current conduction of this kind.

A further embodiment provides that the semiconductor element is embodied as a switchable semiconductor element, in particular as a transistor, and embodies a half-bridge with at least one further switchable semiconductor element. For example, the semiconductor element is configured as a low-side switch of the half-bridge. In particular, the switchable semiconductor element and the further switchable semi-conductor element are each embodied as at least one IGBT. Due to the circuit topology of the half-bridge, the wiring of the low-side switch can, for example, be less reliable, and this adversely affects the service life of the half-bridge. In this example, the reliability of the low-side switch is improved by the overbonding of the wiring elements via the second connecting section on the third line section or is adapted so a longer service life of the half-bridge is achieved.

The invention will be described and explained in more detail below on the basis of the exemplary embodiments represented in the figures.

It is shown in:

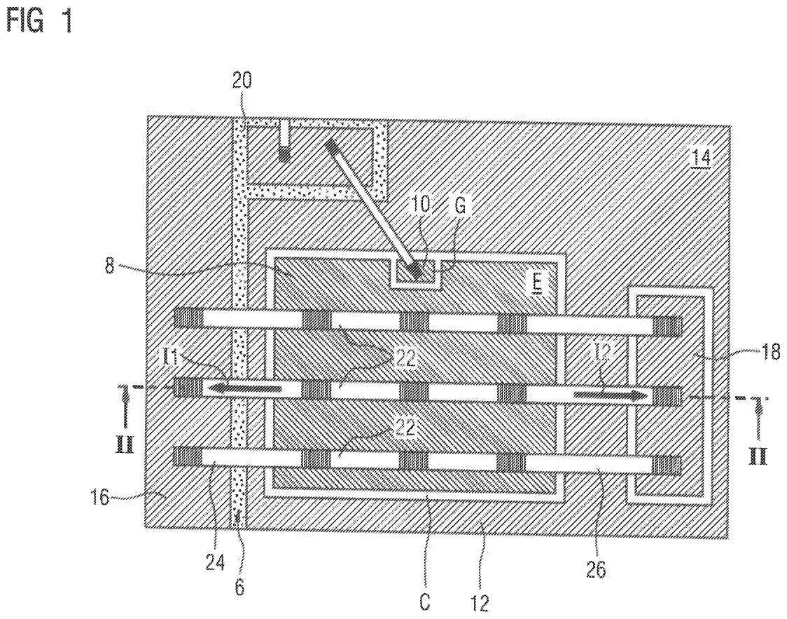

FIG. 1 a schematic representation of a first embodiment of a semiconductor arrangement in a plan view,

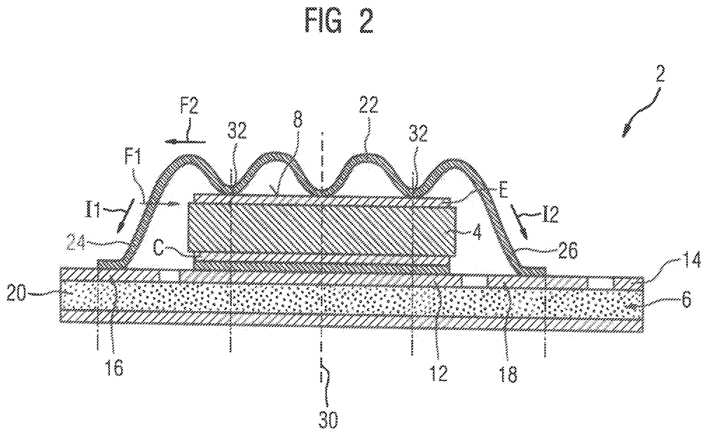

FIG. 2 a schematic representation of the first embodiment of the semiconductor arrangement in a cross-sectional representation,

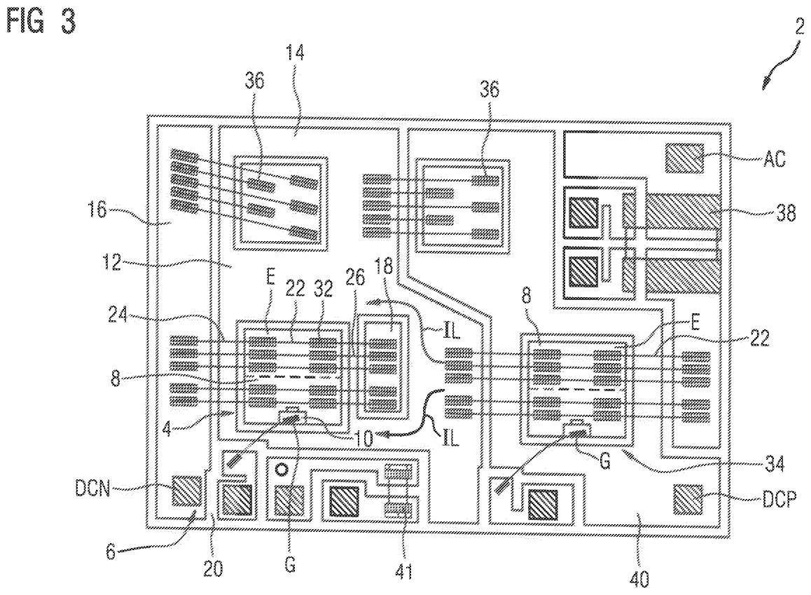

FIG. 3 a schematic representation of a second embodiment of a semiconductor arrangement in a plan view,

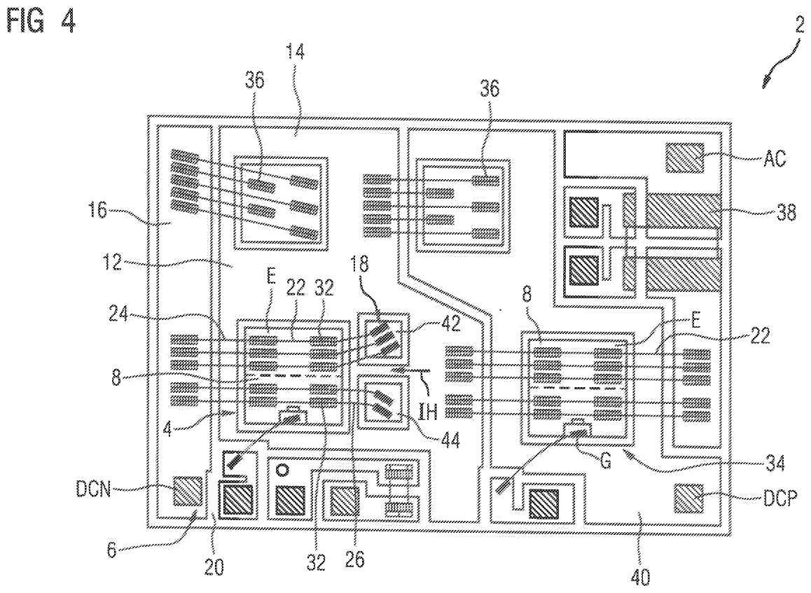

FIG. 4 a schematic representation of a third embodiment of a semiconductor arrangement in a plan view,

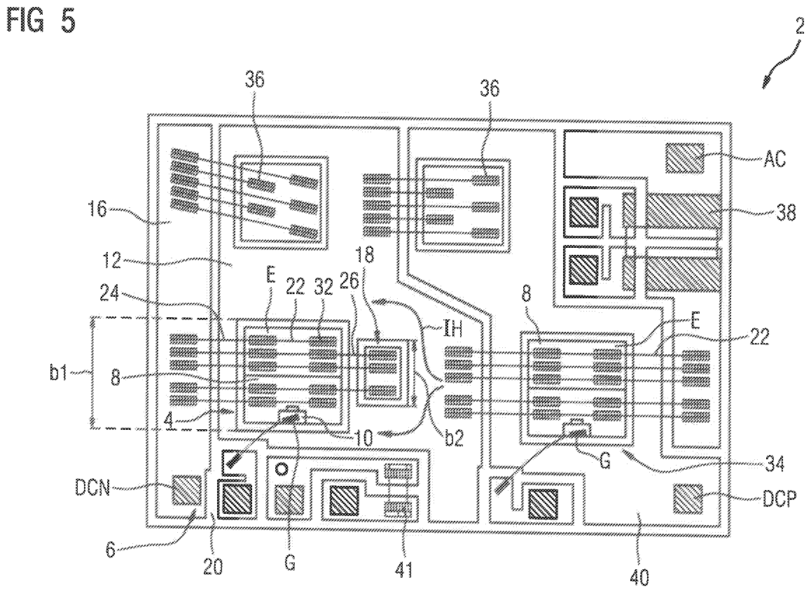

FIG. 5 a schematic representation of a fourth embodiment of a semiconductor arrangement in a plan view,

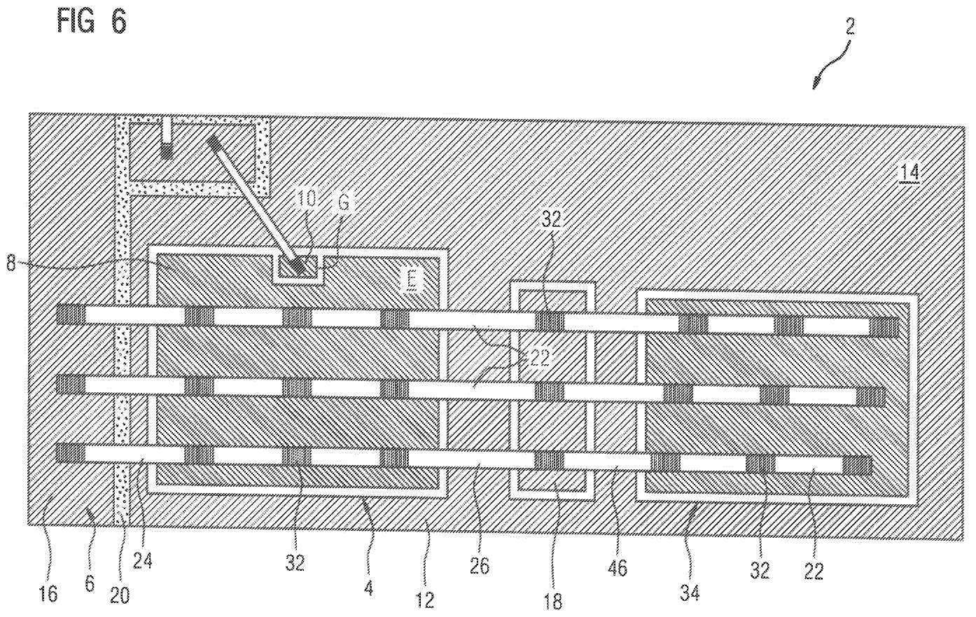

FIG. 6 a schematic representation of a fifth embodiment of a semiconductor arrangement in a plan view,

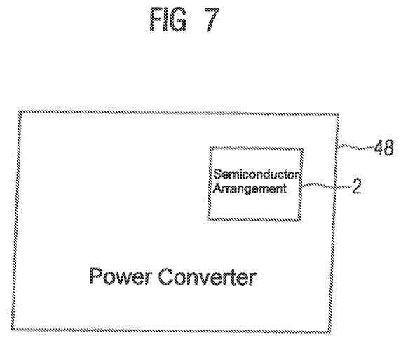

FIG. 7 a schematic representation of a power converter.

The exemplary embodiments explained below are preferred embodiments of the invention. In the exemplary embodiments, the described components of the embodiments respectively represent individual features of the invention to be considered independently of one another, which respectively develop the invention independently of one another too and thus are to be considered as an integral part of the invention, also individually or in a combination other than that shown. Furthermore, the described embodiments can also be supplemented by further features of the invention already described.

Identical reference numerals have the same meaning in the various figures.

FIG. 1 shows a schematic representation of a first embodiment of a semiconductor arrangement 2 in a plan view, which comprises a semiconductor element 4 which is contacted on a substrate 6. By way of example, the semiconductor element 4 is designed as an insulated gate bipolar transistor (IGBT). Further examples of semiconductor elements 4 of this kind are Triacs, thyristors, diodes or other transistor types such as field effect transistors or bipolar transistors. The IGBT comprises a control terminal, which is designed as a gate terminal G, as well as load terminals, which are designed as a collector terminal C and an emitter terminal E, with the collector terminal C, on a side of the semiconductor element 4 facing the substrate 6, being adhesively bonded to the substrate 6.

The emitter terminal E has a contact surface 8, with the gate terminal G having a control contact surface 10 arranged so as to be electrically insulated from the contact surface 8 of the emitter terminal E. The contact surface 8 and the control contact surface 10 have at least one metallic layer which contains, for example, aluminum, copper and/or gold. The IGBT is connected, for example via a soldered or sintered connection, to a first line section 12 of a substrate metallization 14 of the substrate 6. Further, the substrate 6 has a second line section 16 arranged so as to be electrically insulated from the first line section 12 and a third line section 16 embodied in an island-like manner in the first line section 12 and electrically insulated therefrom, with the second and the third line sections 16, 18 of the substrate metallization 14 being arranged on opposite sides of the semiconductor element 4. Furthermore, the substrate 6 comprises a dielectric material layer 20 which includes, for example, a ceramic material, in particular aluminum nitride or aluminum oxide, and has a thickness of 25 μm to 400 μm, in particular 50 μm to 250 μm.

Moreover, the semiconductor arrangement 2 has a plurality of wiring elements 22 for connecting the contact surface 8 of the emitter terminal E to the second and the third line sections 16, 18. The wiring elements 22 are embodied as bonding wires or bonding tapes which extend essentially in parallel, which contain, for example, aluminum, copper and/or gold. Furthermore, the wiring elements 22 each have a first connecting section 24 which connects the contact surface 8 of the emitter terminal E to the second line section 16 of the substrate metallization 14, and a second connecting section 26 which connects the contact surface 8 of the emitter terminal E to the third line section 18 of the substrate metallization 14. The third line section 18, which is connected to the second connecting section 26 of the respective wiring element 22, is arranged in a no-load manner on the substrate 6. The result of the no-load arrangement is that during operation of the semiconductor arrangement 2, a first current I1, in particular a load current, flows from the emitter E via the first connecting sections 24 of the respective wiring elements 22, while a second, in particular negligibly small, current I2 flows via the second connecting sections 26. In particular, the first current I1 is greater than the second current I2 by one hundred times, in particular by one thousand times. Thus, the first connecting section 24 and the second connecting section 26 have an asymmetrical current flow during operation of the semiconductor arrangement 2.

FIG. 2 shows a schematic representation of the first embodiment of the semiconductor arrangement 2 in a cross-sectional representation. The wiring elements 22 are designed as bonding wires and embody a plurality of stitch contacts 32 on the contact surface 8 between the first connecting section 24 and the second connecting section 26, with the connection being produced by means of ultrasonic bonding. The connection of the wiring elements 22 to the contact surface 8 of the semiconductor element 4 is produced by means of looping-through of the wiring elements 22, in particular by means of multi-stitch wedge-to-wedge wire bonding. Multiple bonding is also called “stitching”. Stich contacts 32 of this kind are conventionally also referred to as “stitch bonds” and can be embodied, for example, as “wedge bonds”. The first connecting section 24 and the second connecting section 26 of the respective wiring element 22 are substantially axially symmetrical in respect of an axis of symmetry 30.

If a first current II, in particular a load current, flows via the wiring elements 22, a shear force FI acts on the connections 32, in particular ultrasonic bonding connections. As a result of the overbonding of the wiring elements 22 via the second connecting section 26 on the third line section 18, a counterforce F2 can counteract the shear force FI so the connections 32 are more robust, in particular under load. The result is that a longer service life of the semiconductor arrangement 2 is achieved by the overbonding.

FIG. 3 shows a schematic representation of a second embodiment of a semiconductor arrangement 2 in a plan view, with a half-bridge being embodied with the semiconductor element 4 designed as an IGBT and a further semiconductor element 34 which is likewise designed as an IGBT. The semiconductor elements 4, 34 each have an antiparallel-connected diode 36.

The semiconductor element 4 is configured as a low-side switch of the half-bridge. The first line section 12 of the substrate 6 is connected via a shunt resistor 38 to an AC terminal AC, while the second line section 16 is connected to a negative DC terminal DCN of the half-bridge. The further semiconductor element 34 is connected, in particular adhesively bonded, to a fourth line section 40 of the substrate metallization 14, with the fourth line section 40 being connected to a positive DC terminal DCP of the half-bridge. A load current path IL of the first line section 12 is embodied to extend past the third line section 18 on both sides. Further, the semiconductor arrangement 2 comprises a temperature sensor which is designed, for example, as an NTC thermistor (negative temperature coefficient thermistor). The further embodiment of the semiconductor arrangement 2 in FIG. 3 corresponds to that in FIG. 1 or FIG. 2.

FIG. 4 shows a schematic representation of a third embodiment of a semiconductor arrangement 2 in a plan view. The third line section 18 of the substrate metallization 14 has two wiring islands 42, 44 arranged so as to be electrically insulated from one another and which are each arranged on the substrate 6 in a no-load manner. The second connecting sections 26 of the wiring elements 22 are each connected to one of the wiring islands 42, 44 of the third line section 18. By way of example, three wiring elements 22 are connected to a first wiring island 42 and two wiring elements 22 are connected to a second wiring island 44. The, by way of example, rectangular wiring islands 42, 44 are arranged spaced apart on the substrate 6 in such a way that a main current path 1H is embodied therebetween, between the semiconductor elements 4, 34. The further embodiment of the semiconductor arrangement 2 in FIG. 4 corresponds to that in FIG. 3.

FIG. 5 shows a schematic representation of a fourth embodiment of a semiconductor arrangement 2 in a plan view, with only three of the total of, by way of example, five wiring elements 22 for connecting the contact surface 8 of the semiconductor element 4 to the substrate 6 being connected to the third line section 18 via a second connecting section 26. The semiconductor element 4 has a first width bI on a side facing the third line section 18, while the third line section 18 has a second width b2 which is smaller than the first width bI. A main current path IH of the first line section 12 is embodied to extend substantially symmetrically past the third line section 18 on both sides. The further embodiment of the semiconductor arrangement 2 in FIG. 5 corresponds to that in FIG. 3.

FIG. 6 shows a schematic representation of a fifth embodiment of a semiconductor arrangement 2 in a plan view, with a further semiconductor element 34 being connected via the wiring elements 22, which are provided for connecting the contact surface 8 of the semiconductor element 4, which is embodied, by way of example, as an IGBT, to the second and third line sections 16, 18. The wiring elements 22 have a third connecting section 46 which connects the third line section 18 of the substrate metallization 14 to the further semiconductor element 34. The further semiconductor element 34 is designed, by way of example, as a diode connected antiparallel to the semiconductor element 4. Additionally or alternatively, the further semi-conductor element 34 can comprise at least one further IGBT connected parallel to the semiconductor element 4. The third line section 18 is designed to be operating at no load, that is to say, apart from the wiring elements 22, the third line section 18 is not connected to any further components in an electrically conductive manner. The further embodiment of the semiconductor arrangement 2 in FIG. 6 corresponds to that in FIG. 1 or IG 2.

FIG. 7 shows a schematic representation of a power converter 48 which comprises, for example, a semiconductor arrangement 2.

1.-16. (canceled)

17. A semiconductor arrangement, comprising:
a substrate including a substrate metallization having line sections which are arranged so as to be electrically insulated from one another;
a semiconductor element connected to a first one of the line sections of the substrate metallization and having a contact surface on a side facing away from the substrate; and
a wiring element designed to connect the contact surface of the semiconductor element to the substrate, said wiring element comprising a first connecting section connecting the contact surface to a second one of the line sections of the substrate metallization, and a second connecting section connecting the contact surface to a third one of the line sections of the substrate metallization, with the second one of the line sections and the third one of the line sections of the substrate metallization being designed such that the first connecting section and the second connecting section have an asymmetrical current flow during operation of the semiconductor arrangement.

18. The semiconductor arrangement of claim 17, wherein the semiconductor element is adhesively bonded to the first one of the line sections of the substrate metallization.

19. The semiconductor arrangement of claim 17, wherein the second one of the line sections and the third one of the line sections of the substrate metallization are arranged on opposite sides of the semiconductor element.

20. The semiconductor arrangement of claim 17, wherein a first current, in particular load current, flowing through the first connecting section of the wiring element is greater by one hundred times, in particular by one thousand times, than a second current flowing through the second connecting section of the wiring element.

21. The semiconductor arrangement of claim 17, wherein the third one of the line sections connected to the second connecting section of the wiring element is arranged in a no-load manner on the substrate.

22. The semiconductor arrangement of claim 17, wherein the first connecting section and the second connecting section of the wiring element are substantially axially symmetrical in respect of an axis of symmetry.

23. The semiconductor arrangement of claim 17, wherein the wiring element comprises a third connecting section designed to connect the third one of the line sections of the substrate metallization to a contact surface of a further semiconductor element.

24. The semiconductor arrangement of claim 17, further comprising a plurality of said wiring element for connecting the contact surface of the semiconductor element to the second one of the line sections and the third one of the line sections.

25. The semiconductor arrangement of claim 17, wherein the semiconductor element is wider on a side facing the third one of the line sections than the third one of the line sections, with a main current path of the first one of the line sections being designed to extend past the third one of the line sections on both sides.

26. The semiconductor arrangement of claim 25, wherein the main current path of the first one of the line sections is formed to extend substantially symmetrically past the third one of the line sections.

27. The semiconductor arrangement of claim 24, wherein more of the plurality of said wiring element are connected to the second one of the line sections than to the third one of the line sections.

28. The semiconductor arrangement of claim 24, wherein the third one of the line sections of the substrate metallization comprises at least two wiring islands which are arranged so as to be electrically insulated from one another and which are arranged in a no-load manner on the substrate, wherein each of the plurality of said wiring element is respectively connected to one of the wiring islands of the third one of the line sections via the second connecting section.

29. The semiconductor arrangement of claim 28, wherein the at least two wiring islands are arranged on the substrate in such a way that a main current path is embodied to extend between the at least two wiring islands.

30. The semiconductor arrangement of claim 17, wherein the semiconductor element is designed as a switchable semiconductor element and forms a half-bridge with at least one further switchable semiconductor element.

31. The semiconductor arrangement of claim 30, wherein the switchable semiconductor element is a transistor.

32. A power converter, comprising the semiconductor arrangement of claim 17.

33. A method for producing a semiconductor arrangement, the method comprising:
connecting a semiconductor element to a substrate; and
connecting a contact surface of the semiconductor element to the substrate via a wiring element.

34. The method of claim 32, wherein the semiconductor element adhesively bonded to the substrate.

35. A computer program product, comprising a computer program embodied on a non-transitory computer readable medium comprising commands which, when the computer program is executed by a computer, cause the computer to carry out, in particular thermal, mechanical and/or electrical, behavior of the semiconductor arrangement of claim 17.
